(19) United States
(12) Patent Application Publication
(10) Pub. No.: US 2013/0025645 A1
(43) Pub. Date: Jan. 31, 2013

(54) Asymmetric cell design in solar panels and manufacturing method thereof

(71) Applicants: Yang-Yang Zhou, Hong Kong (CN); Jia-Wei Ma, Banqiao City (TW)

(72) Inventors: Yang-Yang Zhou, Hong Kong (CN); Jia-Wei Ma, Banqiao City (TW)

(73) Assignee: Du Pont apollo Ltd.

(21) Appl. No.: 13/137,186

(22) Filed: Jul. 27, 2011

(51) Int. Cl. H01L 31/05; H01L 31/18

(52) U.S. Cl. 136/244; 438/80; 257/E31.113

(57) ABSTRACT

A thin film photovoltaic module having a plurality of interconnected submodules and a manufacturing method thereof have been disclosed in the present invention. Each submodule has a front electrode layer, a semiconductor layer, and a back electrode layer which have separating lines in each case for forming series-connected photovoltaic cells. The outer cells of two adjacent submodules are united into a single common tap cell for current collection. The separating lines of the two adjacent submodules are disposed mirror-asymmetrically with respect to a perpendicular bisector of the common tap cell. According to the present invention, the thin film photovoltaic module can prevent leakage current and power drop.

### FIELD OF THE INVENTION

The present invention is directed to a thin film photovoltaic module and a manufacturing method thereof. In particular, the photovoltaic module has submodules which are designed mirror-asymmetrically.

### BACKGROUND OF THE INVENTION

A photovoltaic cell (also called solar cell or photoelectric cell) utilizes the conversion of a light energy into an electric energy. The photovoltaic cell has a PIN-junction, wherein I layer acts as the absorber and PN layers provide the drift electric field. When a solar cell receives light, holes and electrons are generated in the intrinsic semiconductor layers due to the energy of the solar light. The holes are drifted toward the P-type semiconductor, and the electrons are drifted toward the N-type semiconductor in the electric field resulting from the PN layers. Consequently, an electric power is produced by the occurrence of electric potential.

As known in the field, the photovoltaic cell can be classified into a wafer type solar cell and a thin film solar cell. The wafer solar cell uses a wafer made of a semiconductor material such as silicon, and the thin film solar cell is made by forming a semiconductor in the form of a thin film on a substrate such as glass.

A monolithic thin film photovoltaic module comprising numbers of cells is manufactured by sequential steps. In a conventional manufacturing process of a thin film photovoltaic module, a front electrode layer is deposited onto a substrate first, then the first electrode layer is laser-scribed, which forms numbers of separating lines; a semiconductor layer is subsequently deposited onto the front electrode and then laser-scribed, which forms numbers of separating lines; a back electrode is then deposited onto the semiconductor, followed by laser-scribing the back electrode layer (or the back electrode layer and the semiconductor layer), which forms numbers of separating lines. By laser-scribing the above-mentioned deposited layers, a thin film photovoltaic module comprised of numbers of unit cells serially connected to each other is obtained.

For some applications, a low voltage is desirable. A technique to provide a module with low voltage but high power can be found in U.S. Pat. No. 7,888,585. To lower the voltage of a photovoltaic module, it is known, as shown in FIG. 1, to subdivide the module into a plurality of submodules (11, 12, 13). Each submodule (11, 12, 13) has a transparent front electrode layer (15), a semiconductor layer (16) and a back electrode layer (17) which have separating lines (18, 19, 20) in each case for forming series-connected strip-shaped photovoltaic cells (C). The outer cells (Cn, C1) of two adjacent submodules (11 and 12 or 12 and 13) are united into a single tap cell (Cn, C1) for current collection. The separating lines (18, 19, 20) of the two adjacent submodules (11 and 12 or 12 and 13) are disposed mirror-symmetrically with respect to their common tap cells. In U.S. Pat. No. 7,888,585, the negative poles and the positive poles of the submodules (11, 12, 13) of the module 10 are connected in parallel for example via an external connection. FIG. 2 shows the number of the connection marked by “S” of module 10 with four submodules (I, II, III, and IV) according to U.S. Pat. No. 7,888,585.

However, the symmetric design may lead to the power drop in some cases. In addition, the symmetric design may lead to the leakage current because the anode of the tap cell is floating (e.g. cell Cn in U.S. Pat. No. 7,888,585) and if the tap cell is photoactive, its anode will be negative biased to the anode of the cell next to the tap cell. If the leakage current occurs, the power of the photovoltaic module will drop. For cell Cn in U.S. Pat. No. 7,888,585, 2 Isc generated from submodules 11 and 12 need to flow through cell Cn while itself can only generate one Isc. This can lead to current and power limitation.

In light of the above-mentioned problems, there is a need for another design for the thin film photovoltaic module. The new design for the photovoltaic module can prevent generating leakage current and power drop and improve the performance of the whole photovoltaic module, accordingly. A thin film photovoltaic module and the manufacturing method thereof have been disclosed in the prevent invention.

### SUMMARY OF THE INVENTION

In some embodiments of the present invention, a thin film photovoltaic module having a plurality of interconnected submodules has been disclosed. Each submodule has a front electrode layer, a semiconductor layer, and a back electrode layer which have separating lines in each case for forming series-connected photovoltaic cells. The outer cells of two adjacent submodules are united into a single common tap cell for current collection. The separating line in the back electrode layer of the common tap cell with a negative pole can be removed, the separating line in the front electrode layer of the common tap cell with a positive pole can be removed, or an additional separating line can be added to the semiconductor layer of the common tap cell with a positive or negative pole, such that the separating lines of two adjacent submodules are disposed mirror-asymmetrically with respect to a perpendicular bisector of the common tap cell between two adjacent submodules. According to the present invention, the thin film photovoltaic module can prevent current leakage and power drop.

In a further embodiment, the present invention is to provide a method for producing a thin film photovoltaic module as defined above, wherein the separating lines of two adjacent submodules are disposed mirror-asymmetrically with respect to the perpendicular bisector of the common tap cell.

The above summary of the present invention is not intended to describe each illustrated embodiment or every implementation of the present invention. The following figures and detailed description more particularly exemplify these embodiments.

### BRIEF DESCRIPTION OF THE DRAWINGS

The present invention may be more completely understood in consideration of the following detailed description of the preferred embodiments in connection with the accompanying diagrams.

FIG. 1 shows a partial view of a thin film photovoltaic module in the prior art.

FIG. 2 shows the connections of a photovoltaic module in the prior art.

FIG. 3A shows a schematic cross sectional view depicting a conventional thin film photovoltaic module.

FIG. 3B shows a schematic cross sectional view depicting the thin film photovoltaic module of one embodiment of the present invention.

FIG. 4A shows a schematic cross sectional view depicting a conventional thin film photovoltaic module.

FIGS. 4B and 4C show schematic cross sectional views depicting the thin film photovoltaic module of another two embodiments of the present invention.

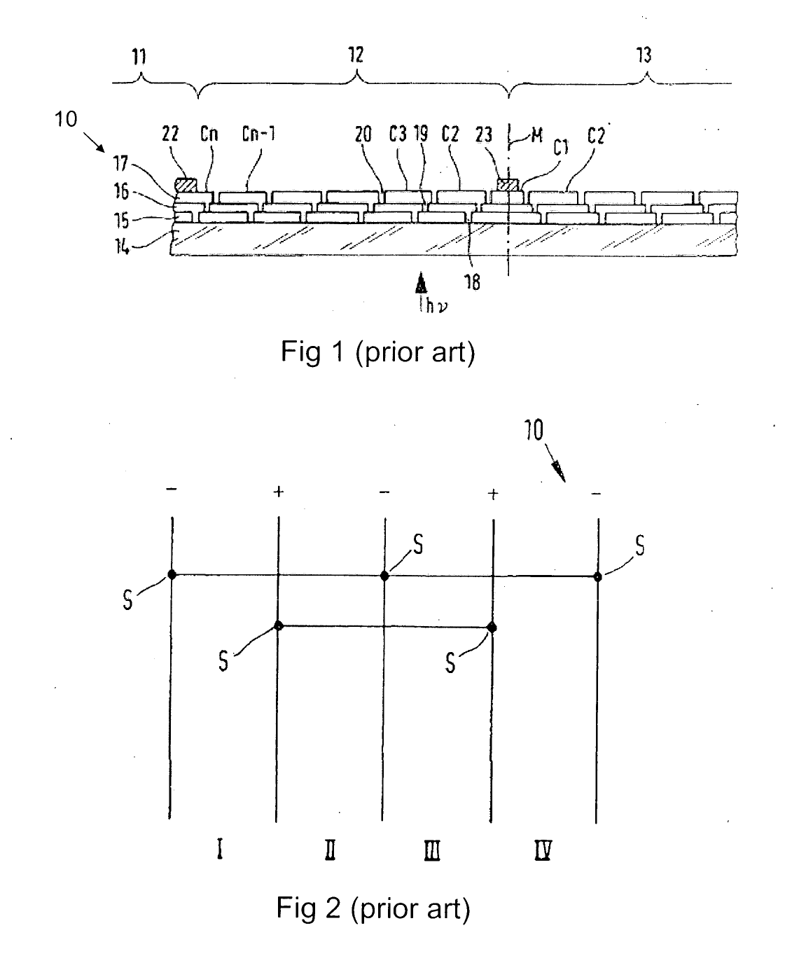

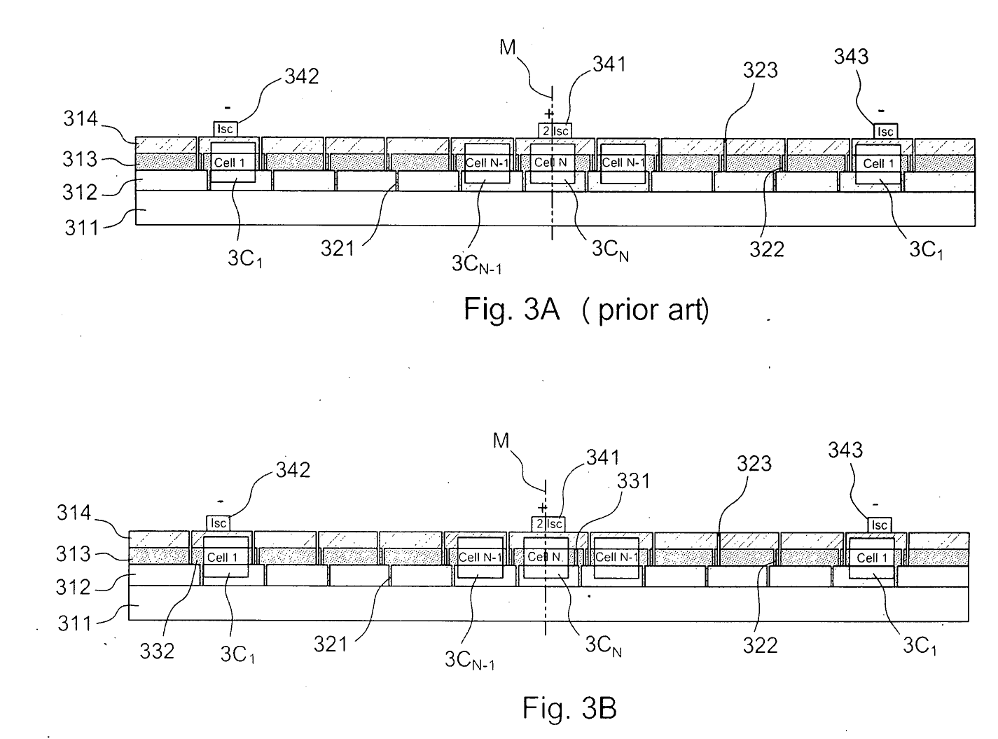

### DETAILED DESCRIPTION OF THE INVENTION

A thin film photovoltaic module and a manufacturing method thereof have been disclosed in the present invention, wherein the methods and principles of photoelectric conversion used in photovoltaic cells are well known to persons having ordinary skill in the art, and thus will not be further described hereafter.

In the specification and claims, the singular forms “a,” “an,” and “the” include the plural unless the context clearly dictates otherwise. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

One embodiment of the present invention is directed to a thin film photovoltaic module formed on a substrate. Said photovoltaic module comprises interconnected submodules with a front electrode layer, a semiconductor layer, and a back electrode layer which are divided by separating lines to form series-connected photovoltaic cells. The two outer cells of each submodule constitute tap cells for current collection. The adjacent outer cells of two adjacent submodules form a single common tap cell. The tap cells are contacted on the back electrode layer with the current collectors for current output. The separating lines of two adjacent submodules are disposed mirror-symmetrically with respect to a perpendicular bisector of the common tap cell, wherein (i) an additional separating line is added to the semiconductor layer of the common tap cell with a positive pole, and the added separating line is closer to the perpendicular bisector of the common tap cell than the other separating lines of the common tap cell, (ii) an additional separating line is added to the semiconductor layer of the common tap cell with a negative pole, and the added separating line is closer to the perpendicular bisector of the common tap cell than the other separating lines of the common tap cell, (iii) the separating line in the front electrode layer of the common tap cell with a positive pole is removed or, (iv) the separating line in the back electrode layer of the common tap cell with a negative pole is removed, such that the resulting separating lines of two adjacent submodules are disposed mirror-asymmetrically with respect to the perpendicular bisector of the common tap cell between two adjacent submodules.

In another embodiment of the present invention, the separating lines of two adjacent submodules are disposed mirror-symmetrically with respect to the perpendicular bisector of the common tap cell formed as mentioned above, wherein an additional separating line is added to the semiconductor layer of the common tap cell with a positive pole and the added separating line is closer to the perpendicular bisector of the common tap cell than the separating line in the front electrode layer of the common tap cell, such that the resulting separating lines of two adjacent submodules are disposed mirror-asymmetrically with respect to the perpendicular bisector of the common tap cell between two adjacent submodules. The embodiment refers to (i) as defined above.

In another embodiment of the present invention, the separating lines of two adjacent submodules are disposed mirror-symmetrically with respect to the perpendicular bisector of the common tap cell formed as mentioned above, wherein an additional separating line is added to the semiconductor layer of the common tap cell with a negative pole and the added separating line is closer to the perpendicular bisector of the common tap cell than the other separating lines of the common tap cell, such that the resulting separating lines of two adjacent submodules are disposed mirror-asymmetrically with respect to the perpendicular bisector of the common tap cell between two adjacent submodules. The embodiment refers to (ii) as defined above.

In another embodiment of the present invention, the separating lines of two adjacent submodules are disposed mirror-symmetrically with respect to the perpendicular bisector of the common tap cell formed as mentioned above, wherein the separating line in the front electrode layer of the common tap cell with a positive pole is removed, such that the resulting separating lines of two adjacent submodules are disposed mirror-asymmetrically with respect to the perpendicular bisector of the common tap cell between two adjacent submodules. The embodiment refers to (iii) as defined above.

In another embodiment of the present invention, the separating lines of two adjacent submodules are disposed mirror-symmetrically with respect to the perpendicular bisector of the common tap cell formed as mentioned above, wherein the separating line in the back electrode layer of the common tap cell with a negative pole is removed, such that the resulting separating lines of two adjacent submodules are disposed mirror-asymmetrically with respect to the perpendicular bisector of the common tap cell between two adjacent submodules. The embodiment refers to (iv) as defined above.

In another embodiment of the present invention, the separating lines of two adjacent submodules are disposed mirror-symmetrically with respect to the perpendicular bisector of the common tap cell formed as mentioned above, wherein when an additional separating line is added to the semiconductor layer of the common tap cell with a positive pole, an additional separating line is added to the semiconductor layer of the common tap cell with a negative pole. The added separating line is closer to the perpendicular bisector of the common tap cell with a positive pole than the other separating lines of the common tap cell with a positive pole. Similarly, the added separating line is closer to the perpendicular bisector of the common tap cell with a negative pole than the other separating lines of the common tap cell with a negative pole. The resulting separating lines of two adjacent submodules are disposed mirror-asymmetrically with respect to the perpendicular bisector of the common tap cell between two adjacent submodules. The embodiment refers to the combination of (i) and (ii) as defined above.

In another embodiment of the present invention, the separating lines of two adjacent submodules are disposed mirror-symmetrically with respect to the perpendicular bisector of the common tap cell formed as mentioned above, wherein when the separating line in the front electrode layer of the common tap cell with a positive pole is removed, an additional separating line is added to the semiconductor layer of the common tap cell with a negative pole. The added separating line is closer to the perpendicular bisector of the common tap cell with a negative pole than the other separating lines of the common tap cell with a negative pole. The resulting separating lines of two adjacent submodules are disposed mirror-asymmetrically with respect to the perpendicular bisector of the common tap cell between two adjacent submodules. The embodiment refers to the combination of (ii) and (iii) as defined above.

In another embodiment of the present invention, the separating lines of two adjacent submodules are disposed mirror-symmetrically with respect to the perpendicular bisector of the common tap cell formed as mentioned above, wherein when the separating line in the front electrode layer of the common tap cell with a positive pole is removed, the separating line in the back electrode layer of the common tap cell with a negative pole is removed. The resulting separating lines of two adjacent submodules are disposed mirror-asymmetrically with respect to the perpendicular bisector of the common tap cell between two adjacent submodules. The embodiment refers to the combination of (iii) and (iv) as defined above.

In another embodiment of the present invention, the separating lines of two adjacent submodules are disposed mirror-symmetrically with respect to the perpendicular bisector of the common tap cell formed as mentioned above, wherein when an additional separating line is added to the semiconductor layer of the common tap cell with a positive pole, the separating line in the back electrode layer of the common tap cell with a negative pole is removed. Furthermore, the added separating line is closer to the perpendicular bisector of the common tap cell with a positive pole than the separating line in the front electrode layer of the common tap cell with a positive pole. The resulting separating lines of two adjacent submodules are disposed mirror-asymmetrically with respect to the perpendicular bisector of the common tap cell between two adjacent submodules. The embodiment refers to the combination of (i) and (iv) as defined.

In another embodiment of the present invention, the separating lines of two adjacent submodules are disposed mirror-symmetrically with respect to the perpendicular bisector of the common tap cell formed as mentioned above, wherein when the separating line in the back electrode layer of the common tap cell with a negative pole is removed, the separating line in the semiconductor layer on the same side where the separating line in the back electrode layer was previously removed is further removed. The resulting separating lines of two adjacent submodules are disposed mirror-asymmetrically with respect to the perpendicular bisector of the common tap cell between two adjacent submodules.

In a further embodiment, the invention is to propose a method for producing a thin film photovoltaic module as defined above. Said photovoltaic module formed on a substrate comprises interconnected submodules with a front electrode layer, a semiconductor layer, and a back electrode layer which are divided by separating lines to form series-connected photovoltaic cells, wherein the separating lines of the two adjacent submodules are disposed mirror-asymmetrically with respect to the perpendicular bisector of the common tap cell which was formed by the adjacent outer cells of adjacent submodules.

The front electrode layer, the semiconductor layer and the back electrode layer are generally applied by chemical or physical vapor deposition. The separating lines in the front electrode layer, the semiconductor layer, and the back electrode layer can be formed mechanically or chemically, e.g., by patterning techniques. These separating lines can also be formed by a laser. As well known in the field, the patterning technique used in the present invention can be, but not limited to, laser-scribing, mechanical means, chemical etching, and photolithography. For example, the chemical etching comprises dry etching, wet etching, and etching paste.

Preferably, the separating line in the back electrode layer is extending downward so that the semiconductor layer is divided into units by said separating line.

For better understanding, the present invention is illustrated below in details by embodiments in the examples with reference to the drawings, which are not intended to limit the scope of the present invention. It will be apparent that any modifications or alterations that can easily be accomplished by those having ordinary skill in the art fall within the scope of the disclosure of the specification.

### EXAMPLE 1

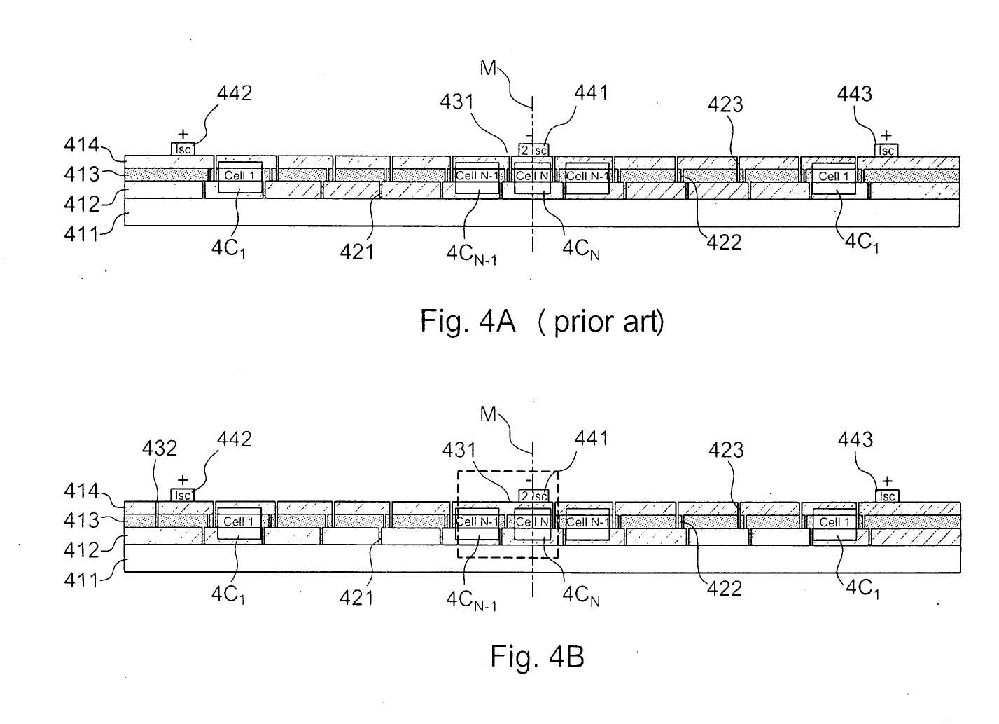

Referring to FIG. 3A, a conventional thin film low voltage photovoltaic module formed on a substrate (311) which comprises two submodules with a common tap cell having a positive pole. Each submodule has a front electrode layer (312), a semiconductor layer (313), and a back electrode layer (314) which are divided by groups of separating lines (321, 322, 323) to form series-connected photovoltaic cells (3C₁ to 3C_{N-1}). Two negative current collectors (342, 343) are in contact with the back electrode layer (314) of the outer cells (3C₁) of the left and right submodules, respectively, and then externally connected, acting as the cathode of the whole module. The positive current collector (341) is in contact with the back electrode layer (314) of the common tap cell (3C_{N}). The separating lines (321, 322, 323) of the two submodules are disposed mirror-symmetrically with respect to the common tap cell (3C_{N}) which has a perpendicular bisector (M). In such case, the anode of the common tap cell (3C_{N}) is floating and if this cell is photoactive, its anode will be negative biased to the anode of the cell (3C_{N-1}), leading to the leakage current generation and the reduction of the power of the whole module.

To solve the problem of the prior art design, the common tap cell (3C_{N}) should be shorted to ensure that no bias exists between anodes of the common tap cell (3C_{N}) and the cell (3C_{N-1}) and no leakage current is generated. To achieve the shortage of the common tap cell (3C_{N}), an asymmetric design strategy is provided. Referring to FIG. 3B, an additional separating line (322) is added to the semiconductor layer (313) of the common tap cell (3C_{N}) in the right submodule at the position (331). Alternatively, the separating line (322) in the semiconductor layer (313) at the position (332) can be moved to the position (331) as the added separating line. The added separating line (322) is closer to the perpendicular bisector (M) of the common tap cell (3C_{N}) than the separating line (321) in the front electrode layer (312) of the common tap cell (3C_{N}). In this way, the common tap cell (3C_{N}) will be photo-inactive.

Since no bias exists between the anodes of the common tap cell (3C_{N}) and the cell (3C_{N-1}) and no leakage current is generated, the power of the whole module can be improved accordingly. An alternative way to short the common tap cell (3C_{N}) is to remove its separating line (321) in the front electrode layer (312) (not shown).

### EXAMPLE 2

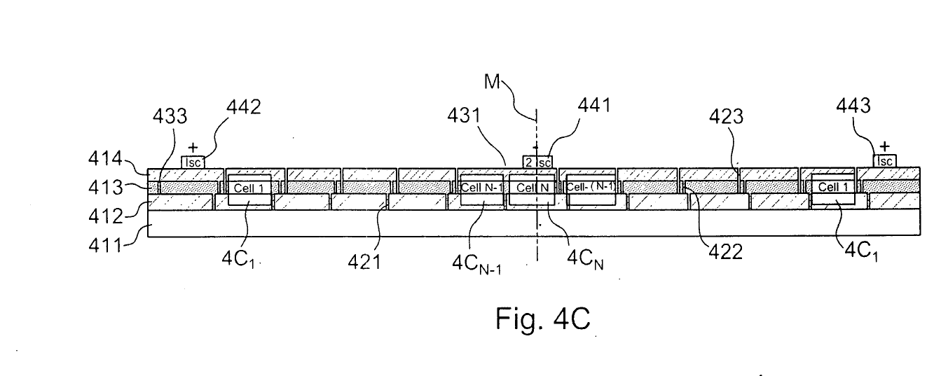

Referring to FIG. 4A, a conventional film photovoltaic module formed on a substrate (411) which comprises two submodules with a common tap cell having a negative pole. Each submodule has a front electrode layer (412), a semiconductor layer (413), and a back electrode layer (414) which are divided by groups of separating lines (421, 422, 423) to form series-connected photovoltaic cells (4C₁ to 4C_{N-1}). Two positive current-collectors (442, 443) are in contact with the back electrode layer (414) of the outer peripheries of the left and right submodules, respectively, and then externally connected, acting as the anode of the whole module. The negative current collector (441) is in contact with the common tap cell (4C_{N}). The separating lines (421, 422, 423) of the two submodules are disposed mirror-symmetrically with respect to the common tap cell (4C_{N}) which has a perpendicular bisector (M). In such case, 2 Isc need to flow through the common tap cell (4C_{N}), wherein one Isc comes from the left submodule of the module and the other comes from the right submodule of the module. However, the photoactive common tap cell (4C_{N}) itself can only generate one Isc, which will limit the 2 Isc of the whole module. Therefore, the total current of the module will be smaller than 2 Isc, leading to the power drop.

To solve the problem of the prior art design, the common tap cell (4C_{N}) should be shorted to ensure that 2 Isc can be generated with the whole module. To achieve the shortage of the common tap cell (4C_{N}), an asymmetric design strategy is provided. Referring to FIG. 4B, the separating line (423) in the back electrode layer of the (4C_{N-1}) in the left submodule is removed at the position (431) or can be moved to the position (432). Please be noted that the separating lines (421, 422, 423) of the photovoltaic module are mirror-asymmetric with respect to the perpendicular bisector (M) of the common tap cell (4C_{N}). In this way, the common tap cell (4C_{N}) will be photo-inactive and the area of the common tap cell (4C_{N}) with the negative pole can increase (as shown by the area indicated by the square in dash lines). With the shortage of the common tap cell (4C_{N}), 2 Isc can be generated, leading to power improvement. Additionally, since the area of the common tap cell (4C_{N}) with the negative pole increases (twice as before), the series resistance of the photovoltaic module is reduced and the power can be improved accordingly. An alternative way to short cell (4C_{N}) is to add an additional separating line (422) to the semiconductor layer (413) of the common tap cell (4C_{N}) in the right submodule, wherein the added separating line (422) is closer to the perpendicular bisector (M) of the common tap cell (4C_{N}) than the separating line (423) in the back electrode layer (414) of the common tap cell (4C_{N}) (not shown).

### EXAMPLE 3

This example illustrates a further improvement of Example 2. Referring to FIG. 4B, when the separating line (423) in the back electrode layer of the (4C_{N}) in the left submodule is removed at the position (431), the common tap cell (4C_{N}) is shorted and photo-inactive. Referring to FIG. 4C, the separating line (422) in the semiconductor layer of the cell (4C_{N-1}) is removed at the position (431). In this design, the separating line (422) in the semiconductor layer (413) to be removed at the position (431) is on the same side where the separating line (423) in the back electrode layer (414) was previously removed. In this way, the common cell (4C_{N}) turns to be photoactive. Alternatively, the separating line (422) in the semiconductor layer (413) at the position (431) can be moved to the position (433). Consequently, the performance of the whole module is improved as one photoactive cell (the common cell) is added to the right submodule. Please be noted that the separating lines (421, 422, 423) of the photovoltaic module are mirror-asymmetric with respect to the perpendicular bisector (M) of the common tap cell (4C_{N}). In addition, the numbers of the photovoltaic cells in the two submodules are not the same. The number of the cells in the left submodule is smaller than that of the cells in the right submodule. That is, the submodules are design mirror-asymmetrically.

Experiment and Results

The results of the symmetric and asymmetric designs are compared. In this experiment, there are two more photovoltaic cells in the asymmetric design in comparison with the symmetric design. The experimental results are shown in Table 1.

TABLE 1

| | Average Performance | | | | |
|---|---|---|---|---|---|
| Design | Voc (V) | Isc (A) | Pmax (W) | FF | Eff (%) |
| N + 2 cells, | 31.255 | 6.857 | [symbol] | 0.735 | 10.069 |
| asymmetric | | | | | |
| N cells, | 30.647 | 6.858 | [symbol] | 0.734 | 9.858 |
| symmetric | | | | | |

[symbol]

indicates data missing or illegible when filed

The experimental results are consistent with the cell design according to the present invention. For the asymmetric design according to the present invention, as the number of the series-connected cells increases, Voc, Pmax, and Eff increase while Isc and FF are comparable to those obtained by the symmetric design. The experimental results confirm the advantages of the asymmetric cell design according to the present invention.

Although the present invention has been described with reference to the illustrative embodiments, it should be understood that any modifications or alterations that can easily be accomplished by persons having ordinary skill in the art will fall within the scope of the disclosure of the specification, drawings, and the appended claims.

1. A thin film photovoltaic module formed on a substrate, comprising interconnected submodules with a front electrode layer, a semiconductor layer, and a back electrode layer which are divided by separating lines to form series-connected photovoltaic cells, the two outer cells of each submodule constituting tap cells for current collection, the adjacent outer cells of two adjacent submodules form a single common tap cell, the separating lines of two adjacent submodules being disposed mirror symmetrically with respect to a perpendicular bisector of the common tap cell, and the tap cells being contact on the back electrode layer with a current collector for current output,
wherein
(i) an additional separating line is added to the semiconductor layer of the common tap cell with a positive pole, and the added separating line is closer to the perpendicular bisector of the common tap cell than the other separating lines of the common tap cell,
(ii) an additional separating line is added to the semiconductor layer of the common tap cell with a negative pole, and the added separating line is closer to the perpendicular bisector of the common tap cell than the other separating lines of the common tap cell,
(iii) the separating line in the front electrode layer of the common tap cell with a positive pole is removed, or
(iv) the separating line in the back electrode layer of the common tap cell with a negative pole is removed,
such that the separating lines of two adjacent submodules are disposed mirror-asymmetrically with respect to the perpendicular bisector of the common tap cell between two adjacent submodules.

2. The thin film photovoltaic module of claim 1, wherein
when an additional separating line is added to the semiconductor layer of the common tap cell with a positive pole, an additional separating line is added to the semiconductor layer of the common tap cell with a negative pole.

3. The thin film photovoltaic module of claim 1, wherein
when the separating line in the front electrode layer of the common tap cell with a positive pole is removed, an additional separating line is added to the semiconductor layer of the common tap cell with a negative pole.

4. The thin film photovoltaic module of claim 1, wherein
when the separating line in the front electrode layer of the common tap cell with a positive pole is removed, the separating line in the back electrode layer of the common tap cell with a negative pole is removed.

5. The thin film photovoltaic module of claim 1, wherein
when an additional separating line is added to the semiconductor layer of the common tap cell with a positive pole, the separating line in the back electrode layer of the common tap cell with a negative pole is removed.

6. The thin film photovoltaic module of claim 1, wherein
when the separating line in the back electrode layer of the common tap cell with a negative pole is removed, the separating line in the semiconductor layer on the same side where the separating line in the back electrode layer was previously removed is removed.

7. The thin film photovoltaic module of claim 4, wherein
when the separating line in the back electrode layer of the common tap cell with a negative pole is removed, the separating line in the semiconductor layer on the same side where the separating line in the back electrode layer was previously removed is removed.

8. The thin film photovoltaic module of claim 5, wherein
when the separating line in the back electrode layer of the common tap cell with a negative pole is removed, the separating line in the semiconductor layer on the same side where the separating line in the back electrode layer was previously removed is removed.

9. The thin film photovoltaic module of claim 1, wherein the separating line in the back electrode layer is extending downward such that the semiconductor layer is divided into units by said separating line.

10. The thin film photovoltaic module of claim 2, wherein the separating line in the back electrode layer is extending downward such that the semiconductor layer is divided into units by said separating line.

11. The thin film photovoltaic module of claim 3, wherein the separating line in the back electrode layer is extending downward such that the semiconductor layer is divided into units by said separating line.

12. The thin film photovoltaic module of claim 4, wherein the separating line in the back electrode layer is extending downward such that the semiconductor layer is divided into units by said separating line.

13. The thin film photovoltaic module of claim 5, wherein the separating line in the back electrode layer is extending downward such that the semiconductor layer is divided into units by said separating line.

14. The thin film photovoltaic module of claim 6, wherein the separating line in the back electrode layer is extending downward such that the semiconductor layer is divided into units by said separating line.

15. The thin film photovoltaic module of claim 7, wherein the separating line in the back electrode layer is extending downward such that the semiconductor layer is divided into units by said separating line.

16. The thin film photovoltaic module of claim 8, wherein the separating line in the back electrode layer is extending downward such that the semiconductor layer is divided into units by said separating line.

17. A method for producing a thin film photovoltaic module formed on a substrate, comprising interconnected submodules with a front electrode layer, a semiconductor layer, and a back electrode layer which are divided by separating lines to form series-connected photovoltaic cells, the two outer cells of each submodule constituting tap cells for current collection, the adjacent outer cells of two adjacent submodules form a single common tap cell, the separating lines of two adjacent submodules being disposed mirror-symmetrically with respect to a perpendicular bisector of the common tap cell, and the tap cells being contact on the back electrode layer with a current collector for current output,
wherein
(i) an additional separating line is added to the semiconductor layer of the common tap cell with a positive pole, and the added separating line is closer to the perpendicular bisector of the common tap cell than the other separating lines of the common tap cell,
(ii) an additional separating line is added to the semiconductor layer of the common tap cell with a negative pole, and the added separating line is closer to the perpendicular bisector of the common tap cell than the other separating lines of the common tap cell,
(iii) the separating line in the front electrode layer of the common tap cell with a positive pole is removed, or
(iv) the separating line in the back electrode layer of the common tap cell with a negative pole is removed,
such that the separating lines of two adjacent submodules are disposed mirror-asymmetrically with respect to the perpendicular bisector of the common tap cell between two adjacent submodules.
